(19) United States
(12) Patent Application Publication
(10) Pub. No.: US 2006/0043067 A1
(43) Pub. Date: Mar. 2, 2006

(54) Yttria insulator ring for use inside a plasma chamber

(75) Inventors: Babak Kadkhodayan, Hayward, CA (US); Rajinder Dhindsa, San Jose, CA (US); Yuehong Fu, Fremont, CA (US)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Lam Research Corporation

(21) Appl. No.: 10/925,923

(22) Filed: Aug. 26, 2004

(51) Int. Cl. H01L 21/306; B44C 1/22

(52) U.S. Cl. 216/67; 156/345.36; 216/74; 216/79

(57) ABSTRACT

A yttria insulator ring for use in a plasma processing apparatus is provided to minimize arcing between the apparatus and a ground extension, while also increasing a mean time between cleanings (MTBC). The yttria insulator ring may be located between a ground extension and a plasma generation zone, or gap, of the chamber of the apparatus, as well as between an edge ring and the ground extension. Compared to a quartz ring, the yttria insulator ring can also provide improved semiconductor substrate uniformity because of improved RF coupling as a result of decreased reactivity and increased dielectric constant.

### BACKGROUND

Plasma processing apparatuses are used to process semiconductor substrates by techniques including etching, physical vapor deposition (PVD), chemical vapor deposition (CVD), ion implantation, and ashing or resist removal. One type of plasma processing apparatus includes a radio frequency (RF) capacitively coupled plasma reactor. RF capacitively coupled plasma reactors may be used for etch processes where plasma is formed in a gap between two electrodes, where one of the electrodes is an RF powered electrode and the other electrode is grounded. The bottom electrode may include various conductive or dielectric materials such as a silicon hot edge surrounding a semiconductor wafer, a quartz insulator ring surrounding the hot edge ring, a dielectric coupling ring beneath the hot edge ring, and one or more dielectric coupling rings which are not exposed to plasma in the plasma reactor.

### SUMMARY

Provided is a yttria insulator ring adapted to be mounted in a plasma chamber such as a plasma etch chamber.

Also provided is a plasma processing apparatus, which includes a substrate support; an upper electrode and a lower electrode, wherein the upper electrode and the lower electrode face each other in a spaced relation forming a gap therebetween, wherein the substrate support includes the lower electrode; an electrostatic chuck forming a substrate support surface; an edge ring surrounding the electrostatic chuck; a ground extension on a peripheral section of the substrate support; and a yttria insulator ring overlying an upper surface of the ground extension.

Also provided is a method of replacing an insulator ring in a plasma chamber, which includes removing a previously used insulator ring from the plasma chamber; and replacing the insulator ring with an insulator ring comprised entirely of yttria (Y₂O₃).

Also provided is a method of plasma etching a semiconductor substrate in a plasma chamber containing an insulator ring entirely of yttria, the method comprising loading a semiconductor substrate into the plasma chamber; supplying process gas to the interior of the plasma chamber and energizing the process gas into a plasma state, plasma etching the semiconductor substrate; and removing the semiconductor substrate from the plasma chamber.

### BRIEF DESCRIPTION OF THE DRAWINGS

FIGS. 1A and B are views of a preferred embodiment of a plasma processing apparatus including a insulator ring as provided herein.

FIGS. 2A and B are cross-sectional views of preferred embodiments of edge rings.

FIGS. 3A, B and C are cross-sectional views of preferred embodiments of insulator rings.

### DETAILED DESCRIPTION

As the size of semiconductor substrates increases, improvements are needed in plasma processing chamber design to address process uniformity requirements and address issues concerning consumable parts used in the chambers. For instance, as wafer size increases it is more difficult to achieve uniform etching across the wafer, especially for difficult to etch dielectric materials such as doped or undoped silicon oxide, e.g., silicon dioxide, fluorinated silicon oxide (FSG), boron phosphate silicate glass (BPSG), phosphate silicate glass (PSG), TEOS deposited silicon oxide, organic and inorganic low-k materials, and the like. For etching such wafer materials it may be necessary to increase power levels supplied to electrodes which energize process gas into a plasma state with the result that consumable parts need replacement more frequently and etch rate uniformity across the wafer can be adversely affected.

In a RF capacitively coupled plasma reactor for processing large substrates such as 300 mm wafers, a secondary ground may also be used in addition to the ground electrode. For example, the substrate support can include a bottom electrode which is supplied RF energy at one or more frequencies, process gas can be supplied to the interior of the chamber through a showerhead electrode which is a grounded upper electrode, and the ground extension can be located outwardly of the bottom electrode. The secondary ground can include an electrically grounded portion which extends generally in a plane containing the semiconductor to be processed but separated therefrom by an edge ring. The edge ring can be of electrically conductive or semiconductive material which becomes heated during plasma generation, i.e., a hot edge ring. Additionally, a plasma confinement ring assembly can be provided outwardly of the showerhead electrode to aid in confining the plasma in the gap between the upper and lower electrodes. The secondary ground can aid the plasma confinement ring assembly in confining the plasma within the gap. A detailed discussion of plasma confinement rings and secondary grounds used in RF capacitively coupled plasma reactors can be found in commonly assigned U.S. Pat. No. 5,534,751 and published U.S. Patent Application No. 2003/0151371A1, both of which are hereby incorporated by reference.

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

Typically, the vacuum chamber walls of the plasma reactor are made of materials that are incompatible to the semiconductor substrate being processed. With confined plasma, there is little or no contamination caused by the chamber walls. Thus, confined plasmas provide a level of cleanliness that is not provided by unconfined plasmas. Generating confined plasma for 300 mm etch applications is difficult because of the higher RF power and higher gas flow rates that are applied during the etching process. While the following embodiments are applicable to 300 mm applications, it will be appreciated by those skilled in the art having the benefit of this disclosure that the apparatuses and methods described herein are not limited to 300 mm applications. The apparatuses and methods described herein may be adapted to be used for applications requiring the confinement of plasma in a high gas flow environment that employ high RF power levels. High gas flow rates refer to flow rates of approximately 1500 sccm and higher, and high RF power levels refer to power levels of approximately 2 W/cm³ and higher of plasma volume.

In a preferred embodiment, the plasma processing apparatus comprises a first electrode operatively coupled to an RF generator, a second electrode, at least one confinement ring, and a ground extension for draining charge from the plasma boundaries. The plasma processing apparatus is configured to receive a gas that is converted into a plasma state by the plasma processing apparatus. By way of example and not of limitation, the gas flow rate pumped into the plasma processing chamber can be 1500 sccm or more. Alternatively, the process gas flow rate into the chamber can be less than 1500 sccm.

The first electrode is preferably configured to receive a semiconductor substrate and has an associated first electrode area that is adapted to support the substrate. The first electrode is preferably operatively coupled to at least one power supply which supplies RF power to the first electrode. The second electrode is separated from the first electrode by a gap in which the plasma is generated. The second electrode is configured to provide a complete electrical circuit for RF power supplied to the first electrode. Additionally, the second electrode has a second electrode area that may vary in size from that of the first electrode area. In a preferred embodiment, the second electrode area is greater than the first electrode area. To generate the plasma within the plasma processing apparatus, RF power is supplied to the first electrode such that the process gas is then converted to a plasma state for processing a semiconductor wafer. By way of example and not of limitation, RF power levels of 2 W/cm³ or more of plasma volume can be applied or the RF power level can be less than 2 W/cm³ of plasma volume. At least one confinement ring is disposed near the first electrode area and the second electrode area, the at least one confinement ring being configured to help confine the plasma in the gap.

The ground extension is adjacent the first electrode and is separated from the first electrode by a dielectric material such as one or more dielectric filler rings. The ground extension drains charge from the plasma boundaries and includes a grounded conductive surface which can increase the confinement window. The term “confinement window” refers to the process parameter space within which confined plasma can be maintained. In particular, it refers to the RF power and gas flow ranges for which a confined operation of the plasma is possible. The ground extension can have various configurations as are discussed in commonly owned U.S. Application 2003/0151371. While capacitive coupling is preferably used to generate the plasma in the processing chamber, it will be appreciated by those skilled in the art that the present apparatus and methods may be adapted to be used with other plasma generating sources such as those used for inductively coupled plasma generation. A preferred capacitive coupled system utilizes a multi-frequency power supply to generate the high electric potential that is applied to a gas to produce the plasma. For example, the power supply can be a dual power frequency power supply operating at 2 MHz and 27 MHz that is included in etching systems manufactured by Lam Research Corporation. It shall be appreciated by those skilled in the art that other power supplies capable of generating plasma in the processing chamber may also be employed and that the RF power source is not limited to RF frequencies of 2 MHz and 27 MHz but may be applicable to a wide range of frequencies.

In a preferred embodiment, the second electrode is a “grounded” electrode configured to cooperate with the first electrode to energize process gas and generate plasma in the processing chamber. However, in order to achieve a decrease in bias voltage at the second electrode and increase in bias voltage at the first “powered” electrode, the second electrode can be configured to communicate less RF power than the first powered electrode. By way of example and not of limitation, the second electrode can be composed of a conductive material such as silicon or silicon carbide and the second electrode can be located 10 to 50 mm from the first electrode. In one embodiment, the ground extension is made from a conductive material and is separated from the first electrode by one or more dielectric filler rings. The ground extension is preferably composed of a conductive material such as aluminum or silicon and the filler ring(s) can be composed of quartz. One or more confinement rings can be used to confine the plasma to the volume defined by the confinement rings. By way of example, the confinement rings can be composed of quartz. The grounded second electrode can have a greater surface area than the powered first electrode. It is hypothesized that the plasma is contained because the area ratio, i.e., the ratio defined by dividing the second electrode area by the first electrode area, determines the bias voltage on the substrate that is clamped to the powered RF electrode. The greater the area ratio between the grounded second electrode and the powered first electrode, the greater the bias voltage at the powered first electrode. Also, the bias voltage on the grounded second electrode and, especially, at the confinement rings is decreased if the area ratio is increased. A reduced bias at the confinement rings will enable them to charge to the same electric potential as the plasma and, therefore, better repel the plasma away from the rings. Thus, the combination of the ground extension disposed near the powered first electrode and the increased surface area of the grounded second electrode with respect to the first electrode increases the size of the confinement window for the plasma processing chamber.

In processing semiconductor substrates in capacitively coupled plasma reactors, it is desirable to confine the plasma in a gap between upper and lower electrodes. In processing larger size substrates such as 300 mm wafers, the ground extension is preferably located outside of an electrostatic chuck and an edge ring may be located between the electrostatic chuck and the ground extension. In dual frequency plasma chambers wherein high and low frequencies are used to generate the plasma and form a bias on a substrate, varying amounts of the two frequencies will couple to an upper electrode and the ground extension.

This RF coupling to the ground extension affects the etch uniformity on the substrate. As the ground extension is in close proximity to the edge ring, a dielectric material in the form of an insulator ring can be used to cover the ground extension to prevent voltage breakdown, or arcing, between the edge ring and the ground extension. This insulator ring can also serve to protect the ground extension from attack by the plasma.

Quartz insulator rings may be used to minimize this arcing and contamination. A dielectric insulator ring comprising quartz has the shortest RF lifetime of the consumable materials present in a plasma chamber. The replacement of consumable materials and associated mean time between cleanings (MTBC) for plasma chambers is application specific. Currently, the MTBC for high aspect ratio contact applications (HARC) using the 2300 Exelan™ plasma chamber, manufactured by Lam Research Corporation, the assignee of the present application, is dictated by replacement of a quartz insulator ring at 215 RF hours.

In plasma processing apparatuses, the MTBC can be used to determine how many cycles may be run before a chamber should be opened and taken out of production. As such, in order to extend the MTBC, a dielectric insulator ring with a longer RF lifetime is provided herein.

During processing of semiconductor wafers in plasma chambers, wherein a single wafer is supported on a lower electrode and plasma is generated in a gap between the wafer and an upper electrode such as a powered or grounded showerhead electrode, plasma processing at the edge region of the wafer may be affected by substrate support parts, such as edge ring arrangements, and/or parts surrounding the edge ring arrangement such as a dielectric insulator ring located on the substrate support. The intensity of capacitive coupling of RF energy to the plasma in the vicinity of the wafer edge is directly proportional to the dielectric constant and thickness of a material located between the plasma and the lower electrode. By increasing capacitance it is possible to increase RF coupling. Because capacitance c=ε₀·k·A/d wherein ε₀ is a universal constant (8.85·10⁻¹²), k is the dielectric constant of the material, A is the cross sectional area of the dielectric material and d is the thickness of the dielectric material. Thus, to increase capacitance, the dielectric constant can be increased and/or the thickness can be decreased. Accordingly, for a particular insulator ring design, use of a higher dielectric constant material with the same thickness and area allows the capacitance to be increased. By using higher dielectric constant materials for the insulator ring, it is possible to increase the intensity of capacitive coupling of RF energy to the plasma in the vicinity of the semiconductor substrate edge, and thereby increase the processing rate, such as the etch rate. Therefore, insulator ring materials having higher dielectric constants can increase the etch rate at an edge of a semiconductor substrate and increase the etch rate uniformity of the processed semiconductor substrate.

While the dielectric constant of yttria is approximately 11, the dielectric constant of quartz is only approximately 3.5. Accordingly, use of a dielectric ring made entirely of yttria can considerably improve the coupling of RF to a ground extension covered by the yttria ring, compared to use of a quartz dielectric ring. Improved coupling of RF to the ground extension improves plasma confinement in the gap and increases the etch rate at the edge of the wafer substrate. This increase in the etch rate at the edge of the wafer can improve the critical dimension and etch rate uniformity across the wafer substrate.

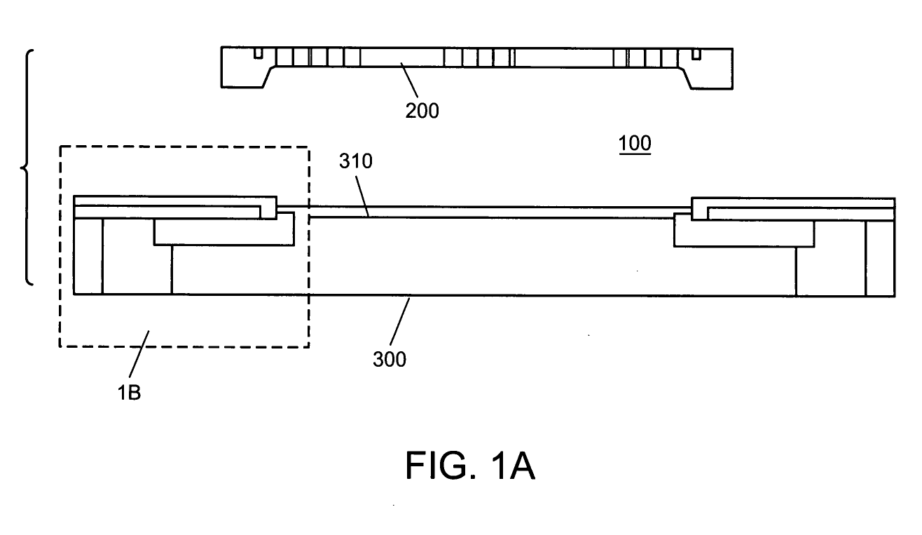

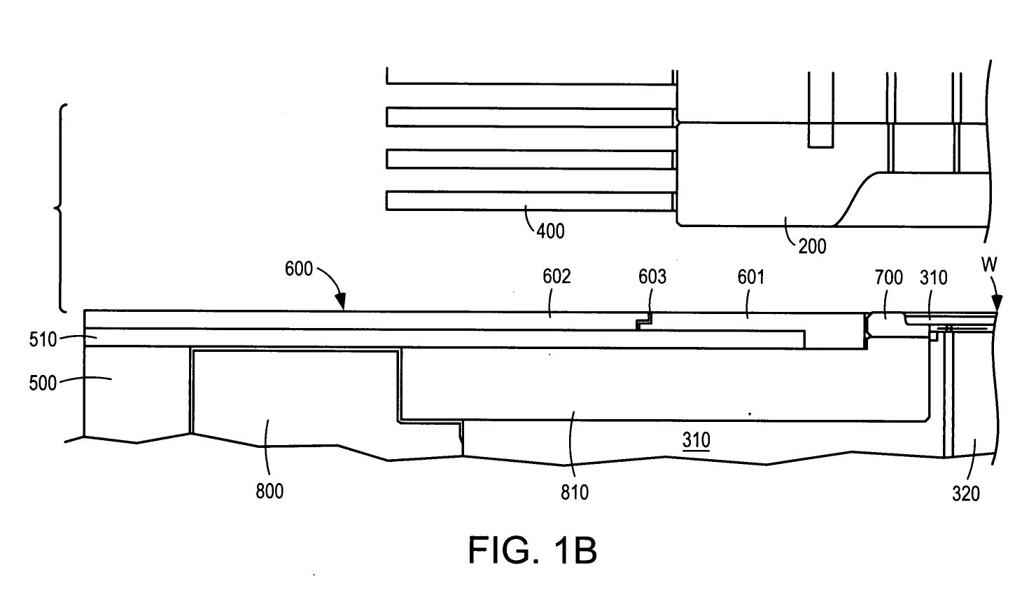

In FIGS. 1A-B, a plasma processing apparatus in the form of a capacitively coupled plasma reactor is provided. In FIG. 1A, the capacitively coupled plasma reactor includes a plasma chamber 100, an upper showerhead electrode 200, (such as the stepped showerhead electrode disclosed in commonly assigned U.S. Pat. No. 6,391,787B1, the entire disclosure of which is hereby incorporated by reference), a substrate support 300, and a confinement ring arrangement 400.

In FIG. 1B, which is an expanded portion of 1B in FIG. 1A, a substrate support includes a ground extension comprising an annular sleeve 500 and a thin annular ring 510 on top of the sleeve 500, a dielectric insulator ring 600 covering the upper surface of the conductive ring 510, an edge ring 700 located between the dielectric ring 600, an optional coupling ring (not shown) below the edge ring, insulator filler rings 800, 810, bottom electrode 310 and an electrostatic chuck (ESC) 310.

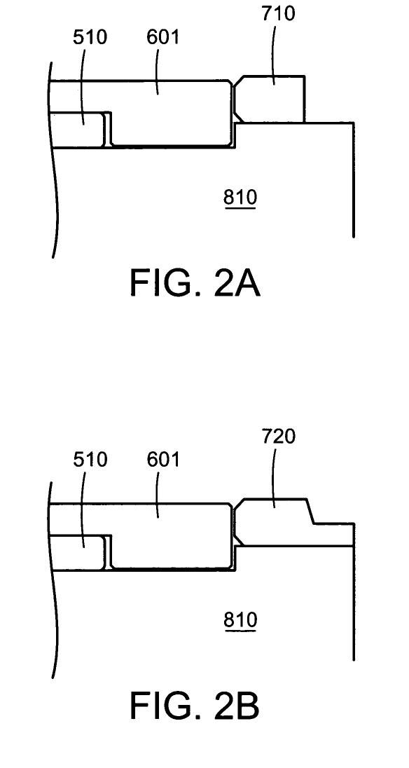

Edge ring 700 can be of electrically conductive material and located in contact with an outer edge of the bottom electrode 310. The edge ring 700 may be made in any shape, preferably a symmetrical shape, in order to provide a more uniform ground for the plasma in the plasma etch chamber 100. For example, as illustrated in FIG. 2A, an edge ring 710 with a rectangular cross-section may be used. However, the edge ring can have any desired configuration, e.g., as illustrated in FIG. 2B (and FIGS. 1A and 1B), an edge ring 720 with one flange (or more) may be used, where the orientation of the one or more flanges, as well as the length and width of the edge ring may be provided.

The edge ring 700 is preferably made of an electrically conductive material such as silicon and silicon carbide. Additionally, because the edge ring 700 is exposed directly to plasma, it is desirable to use highly pure materials, such as single crystal silicon, polycrystalline silicon, CVD silicon carbide, or the like in order to minimize contamination of the plasma. However, the edge ring can be made of other materials such as quartz, aluminum oxide, aluminum nitride, silicon nitride, etc. Further discussion on edge rings and focus rings can be found in commonly assigned U.S. Pat. Nos. 5,805,408; 5,998,932; 6,013,984; 6,039,836, and 6,475,336, which are hereby incorporated by reference.

The ground extension 500 is preferably configured to include an annular axially extending portion 508 surrounding insulator 800 and a laterally extending portion 510 overlying insulators 800, 810 and separated from an outer periphery of substrate W by the edge ring. The ground extension 500 and the confinement ring arrangement 400 cooperate to confine plasma in the gap 100. The ground extension 500 confines the plasma by draining charge from the plasma without affecting the plasma charge density that is directly above the lower electrode 310. Other examples of ground extensions are provided in commonly owned US Patent Application Publication No. 2003/0151371 A1, the entire disclosure of which is hereby incorporated by reference.

The ground extension 500 is preferably an electrically conductive material, such as aluminum, silicon, silicon carbide, etc. For example, aluminum may be used because of its high electrical conductivity and relatively low cost. However, if the ground extension is made of aluminum, the ground extension 500 may chemically react with plasma within the gap and cause impurities within the corrosive process gas and/or plasma species and result in contamination of the processed semiconductor substrates.

This reaction between an aluminum ground extension 500 (or any other plasma reactive material) and the process gas/plasma species may be minimized by using the dielectric insulator ring 600 to insulate the aluminum ground extension 500 from the plasma. As such, using a dielectric ring 600 to protect the ground extension 500 from exposure to the plasma in a plasma chamber 100, can minimize contamination of the semiconductor substrate.

As mentioned above, and as illustrated in FIGS. 1A and 1B, a dielectric ring 600 may be used to separate an edge ring 700 from a ground extension 500 and chemically isolate the ground extension 500 from plasma in a plasma chamber 100, thus minimizing arcing between the edge ring 700 and the ground extension 500 and chemical reaction between the ground extension 500 and process gas/plasma reactive species in a plasma chamber 100. Thus, the dielectric ring 600 is preferably sized to fill a region between the edge ring 700 and an outer periphery of the ground extension 500, and more preferably, the dielectric ring 600 is sized to cover the entire upper surface of the ground extension 500.

A dielectric ring 600 made entirely of yttria is relatively inert to fluorine containing gases used in plasma etching and has a high dielectric constant. Compared to quartz, yttria has several advantages. First, yttria has a higher sputter threshold energy than quartz, and therefore is more sputter resistant. Second, yttria tends to not form volatile species with fluorine chemistries, therefore yttria dielectric rings may last longer and lead to a longer mean time between replacing the dielectric rings, thus increasing the MTBC of the apparatus. Third, yttria has a higher dielectric constant, on the order of 11, while quartz has a dielectric constant of about 3.5 which allows a thinner ring of yttria to be used and attain desired coupling of RF between the ground extension 500 and the plasma.

Another advantage of using yttria for ring 600 is that more effective use of fluorine containing process gas can be obtained. That is, due to formation of volatile compounds when fluorocarbon process gases are used in conjunction with quartz dielectric rings, the concentration of fluorine species at the edge of the wafer can be deleted, resulting in a lower edge etch rate and lack of uniformity in etching across the wafer substrate compared to use of a yttria ring. Since a yttria ring is more sputter resistant than a quartz dielectric ring, and does not readily form fluorine compounds, use of a yttria ring can result in a more chemically uniform plasma which can further improve the critical dimension and etch rate uniformity across the wafer substrate.

Also, due to a lower reactivity in general, a yttria ring 600 may also be used with various process gases which may not be compatible with or unduly attack a quartz dielectric ring. For example, exemplary process gases in a plasma processing apparatus that includes a yttria ring may include Ar, O₂, and fluorocarbons such as C₄F₈, C₃F₆ and CHF₃ for etching materials such as silicon oxide.

In an exemplary process of using a yttria ring 600 in a plasma etch chamber, an etch gas can comprise 300 standard cubic centimeters per minute (sccm) of Ar, 12 sccm of O₂, and 20 sccm of C₄F₈ at a chamber pressure of 50 millitorrs, the plasma being generated by supplying 3 kilowatts of RF power to an upper electrode and/or a lower electrode during etching of a silicon oxide layer on a semiconductor substrate. Additionally, RF frequencies of 2 MHz, 13.5 MHz, 27 MHz, 40 MHz, 60 MHz and 100 MHz may preferably be applied to plasma generating electrodes in the plasma processing apparatus.

A yttria insulator ring may be used in any plasma chamber wherein plasma is generated by capacitive coupling, inductive coupling, microwave, magnetron or other technique. The yttria insulator ring may be used as original equipment in a plasma chamber, or as a replacement part for a dielectric ring in another plasma chamber. Besides etching, the yttria ring may be used in chambers for plasma PVD, CVD, ion implantation, etc.

Yttria insulator rings preferably include a yttria matrix extending between opposed surfaces thereof. Yttria insulator rings preferably include over 50 wt % yttria, more preferably over 90 wt % yttria, and most preferably over 99 wt % yttria. Additionally, the yttria insulator ring preferably contains less than 1000 ppm, or more preferably less than 500 ppm, of impurities such as silicon, aluminum, calcium, iron and/or zirconium. For example, one preferred yttria insulator ring includes 99% or more yttria with a density greater than 4.5 g/cm³, preferably a density greater than 4.75 g/cm³. One suitable Y₂O₃ material is available from Custom Technical Ceramics, Inc. located in Arada, Colo., the material being 99.9% pure yttrium oxide with impurities of 20 ppm La₂O₃, 10 ppm Pr₆O₁₁, 8 ppm Nd₂O₃ less than 50 ppm other rare earth oxides, 40 ppm Si, 30 ppm Ca, 18 mm Fe, <1 ppm Cu, 3 ppm Ni, <1 ppm mg, 2 ppm Pd, the material being provided in bulk forms vin slip casting. A preferred insulator ring, for example, would include a thermally deposited or sintered yttria ring of 99.9 wt % or more yttria with less than a total of 500 ppm of impurities. The yttria insulator ring can be made by any suitable technique including CVD, sputtering, sintering, etc.

In coupon tests used to measure corrosion rates, the tests have shown that a yttria insulator ring with 99.9 wt % or more yttria would be expected to have an RF lifetime at least approximately five, and perhaps as large as ten, times the RF lifetime of a quartz dielectric ring. Accordingly, by using a yttria insulator ring in a plasma processing apparatus, the insulator ring may become a non-factor in determining down time for servicing of such plasma processing apparatuses, as other consumable parts, such as an edge ring, may have shorter RF lifetimes.

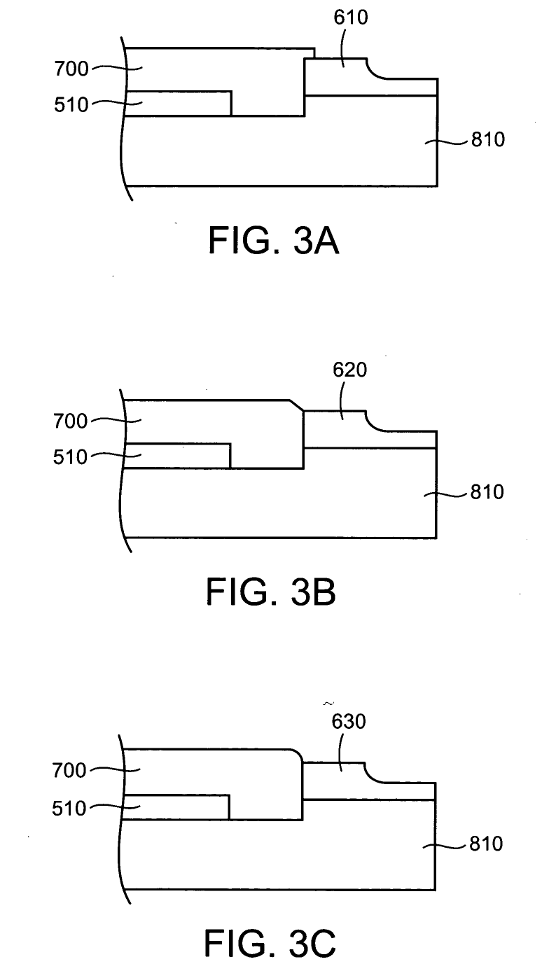

A yttria insulator ring 600 preferably has a symmetrical shape, such as a circular ring, an oblong ring, etc. The shapes of the yttria ring 600 and the edge ring 700 may also be configured to provide a geometric interface between adjacent surfaces of the dielectric ring 600 and the edge ring 700. For example, as illustrated in FIG. 1B, the edge ring 700 may be thicker than the ring 600 and have a tapered surface extending toward the dielectric ring 600. Alternately, the yttria ring 600 may be shaped, for example, as illustrated in FIGS. 3A-C, with a stepped shape 610, a tapered shape 620, or a rounded shape 630.

A yttria insulator ring 600 is preferably sized to provide insulation for the ground extension 500 from other portions of the apparatus. For example, a yttria ring 600 is preferably sized to cover the upper surface of the ground extension 500 outwardly of the edge ring 700, as illustrated in FIG. 1B. It is preferable that the yttria ring 600 be sized to cover one or more surfaces of the ground extension 500 to electrically and chemically isolate the ground extension from other portions of the apparatus.

Additionally, a yttria ring 600 preferably has an inner diameter at least as large as an outer diameter of a substrate, such as a wafer, being processed in the plasma chamber. The outer diameter of the solid yttria dielectric ring 600 preferably varies depending upon the design of the plasma processing apparatus including the width of the ground extension 500 and the plasma chamber. The thickness of the yttria ring 600 can be adapted to the chamber design and/or process carried out therein. For example, the ring 600 can have a uniform or nonuniform thickness such that an upper surface thereof matches that of the ring 700. If a portion of the ring 600 contacts dielectric part 800, 810, the ring 600 may be stepped such that a thicker portion overlies part 800, 810 and a thinner portion overlies ground extension 500, 510.

As a non-limiting example, a yttria ring 600 for use in a 2300 Exelan™ plasma etch chamber would preferably be sized with an inner diameter of approximately 8 to 12 inches (200 to 300 mm) and an outer diameter of 9 to 14 inches (228 to 356 mm) for a corresponding 8 to 12 inch (200 to 300 mm) wafer, respectively, and a uniform or nonuniform thickness of approximately 0.1 to 0.2 inch (2.5 to 5 mm).

The yttria ring 600 may be a multi-part ring, e.g., at least two component rings, possibly with overlapping, and optionally interlocking, segments between the component rings, where the component rings may be concentric or overlapping rings with different diameters. For example, as illustrated in FIG. 1B, the yttria ring 600 has two concentric rings with overlapping edges, i.e., an inner component ring 601 and an outer component ring 602 with an interlocking portion 603. Such a design, for example, would allow for replacement of the inner or smaller component ring 601, were it to need replacing, without the need for replacing the outer or larger diameter component ring 602. The outer component ring 602 would tend to not degrade as quickly as the inner component ring 601, as the inner component ring 601 may be more exposed to the plasma in the gap than the outer component ring 602 depending upon the position of the interlocking portion 603. Use of a dielectric ring 600 comprising at least two component rings 601, 602 could therefore result in cost savings, as only the component ring 601, for example, that has been more eroded would have to be replaced.

A yttria ring 600 offers several advantages in plasma processing semiconductor substrates. First, it allows for the localized enhancement, or intensification, of the plasma density near the edge of a substrate such as a silicon wafer during plasma processing. Furthermore, the etch uniformity may be optimized without significantly affecting other etch characteristics such as the etch rate at the center of the wafer. In the case of wafer processing, the etch rate near the edge of the wafer may be controlled by varying the localized power coupling through the plasma. Namely, by using a yttria insulator ring, more of the RF current is coupled through the plasma in the region near the edge of the wafer. The yttria ring can also help maintain a more uniform plasma density while increasing the energy of the ions in the wafer edge region.

It will be appreciated by those skilled in the art that additions, deletions, modifications, and substitutions not specifically described herein may be made without departing from the spirit and scope of the appended claims.

What is claimed is:

1. A yttria insulator ring comprising a yttria matrix extending between upper and lower surfaces thereof, wherein the yttria ring is adapted to be mounted in a plasma chamber on a peripheral region of a lower electrode and overlie at least part of an upper region of a ground extension.

2. The yttria ring of claim 1, wherein the ring comprises at least 50 wt % yttria, at least 90 wt % yttria, at least 95 wt % yttria or at least 99.9 wt % yttria.

3. The yttria ring of claim 1, wherein the yttria ring consists of sintered yttria.

4. The yttria ring of claim 1, wherein the yttria ring is pure yttria with less than 100 ppm of each of silicon, aluminum, calcium, iron, and zirconium or less than a total of 500 ppm of silicon, aluminum, calcium, iron, and/or zirconium.

5. The yttria ring of claim 1, wherein the yttria ring has an inner diameter larger than 200 mm or larger than 300 mm and a thickness of at least 0.1 inch.

6. The yttria ring of claim 1, wherein the yttria ring is a monolithic ring or multi-part ring such as two component rings which are concentric or overlapping.

7. The yttria ring of claim 6, wherein the yttria ring comprises two component rings which have different diameters and overlap at an interface between the two component rings.

8. The yttria ring of claim 1, wherein the yttria ring has a density of at least 4.5 g/cm³ or at least 4.75 g/cm³.

9. The yttria ring of claim 1, having a dielectric constant of approximately 11.

10. A plasma processing apparatus, comprising the yttria ring of claim 1 wherein the yttria ring is mounted on a substrate support in a vacuum chamber of the plasma processing apparatus; the substrate support including a grounded or RF powered electrode, an edge ring and a ground extension, the yttria ring surrounding the edge ring and overlying at least part of the ground extension.

11. The plasma processing apparatus of claim 10, wherein said plasma processing apparatus comprises a plasma etching apparatus.

12. A method of replacing a dielectric ring in a plasma chamber, comprising:
removing a used or worn dielectric insulator ring from said plasma chamber; and
replacing said used or worn dielectric insulator ring with a replacement dielectric ring comprising solid yttria (Y₂O₃).

13. The method of claim 12, wherein said replacing comprises replacing said used or worn dielectric ring with a replacement dielectric ring comprising at least 99 wt % yttria.

14. The method of claim 12, wherein said replacing comprises replacing said used or worn dielectric ring with a replacement dielectric ring comprising at least 99.9 wt % yttria.

15. The method of claim 12, wherein said replacing comprises replacing said used or worn dielectric ring with a replacement dielectric ring consisting entirely of yttria.

16. The method of claim 12, wherein said used or worn dielectric ring comprises two or more component rings, wherein at least two of the component rings have different diameters,
wherein said removing said used or worn dielectric ring from said plasma chamber comprises removing at least one used or worn component ring, and
wherein said replacing said used or worn dielectric ring with said replacement dielectric ring comprising yttria comprises replacing at least one used or worn component ring of said used or worn dielectric ring with at least one replacement component ring comprising the yttria ring of claim 1.

17. The method of claim 16, wherein said replacing at least one used or worn component ring of said used or worn dielectric ring with at least one replacement component ring comprises overlapping at least one replacement component ring with a remaining at least one other component ring.

18. The method of claim 16, wherein said replacing at least one used or worn component ring of said used or worn dielectric ring with at least one replacement component ring comprises interlocking at least one replacement component ring with a remaining at least one other component ring.

19. A method of manufacturing a semiconductor substrate, comprising:
opening a plasma chamber;
replacing a used or worn dielectric insulator ring with a replacement dielectric ring made entirely of yttria;
closing said plasma chamber;
transferring a semiconductor substrate into said plasma chamber;
plasma etching said semiconductor substrate; and
removing said semiconductor substrate from said plasma chamber.

20. The method of claim 19, wherein said plasma etching comprises applying radio frequency power to a lower electrode, an upper electrode or both an upper and a lower electrode.

21. The method of claim 20, wherein said radio frequency power is applied at radio frequencies of approximately 2 MHz, 13.5 MHz, 27 MHz, 40 MHz, 60 MHz or 100 MHz.

22. The method of claim 19, wherein said plasma etching occurs in a process gas including one or more of Ar, O₂, C₄F₈, C₃F₆ or CHF₃.
